(19) United States
(12) Patent Application Publication
(10) Pub. No.: US 2015/0001697 A1
(43) Pub. Date: Jan. 1, 2015

(54) SELECTIVE TREATMENT OF LEADFRAME WITH ANTI-WETTING AGENT

(71) Applicant: STMicroelectronics SDN BHD, Muar (MY)

(72) Inventor: Yh Heng, Muar (MY)

(21) Appl. No.: 13/931,307

(22) Filed: Jun. 28, 2013

(51) Int. Cl. H01L 23/495; H01L 23/00

(52) U.S. Cl. CPC H01L 23/49575; H01L 24/85
USPC 257/676; 438/123

(57) ABSTRACT

Embodiments of the present disclosure are directed to a leadframe packages that include a leadframe having a surface that is selectively treated with chemicals that reduce the wettability of the surface and thereby reduce adhesive flow on the surface and methods of forming a packing comprising same. In one embodiment there is provided a leadframe having an upper surface that includes a first portion that is treated with an anti-epoxy bleed out chemical and a second portion that was not treated with the anti-epoxy bleed out chemical. A semiconductor die is attached to the upper surface of the leadframe at the second portion via an epoxy adhesive.

### BACKGROUND

1. Technical Field

Embodiments of the present disclosure are directed to leadframe packages and methods of making same.

2. Description of the Related Art

Leadframe packages are widely used in the semiconductor industry and, in general, provide low cost solutions with relatively straight forward assembly processing. However, there remains various obstacles for maintaining suitable adhesion between various materials within leadframe packages.

Generally described, leadframes have a roughened upper surface in order to increase the adhesion with adhesive materials and encapsulation material that may be provided over the leadframes during assembly processing. For instance, when adhesive materials, such as epoxy glue, are used to adhere a semiconductor die to the upper surface the leadframe, the roughened surface of the leadframe increases the adhesion strength with the glue.

Unfortunately, however, the roughened surface of the leadframes also increases the wettability of the surface. That is, the glue flows or bleeds on the roughened surface of the leadframe due to capillary effects caused by the roughened surface. In particular, FIG. 1A shows a die 12 attached to an upper surface 14 of a die pad 16 of a leadframe 18 by epoxy glue 20 that flowed outwardly due to capillary effects. The flow of the epoxy glue 20 is often referred to as epoxy bleed out (EBO). As a result of the EBO, the epoxy glue 20 has a larger footprint on the upper surface 14 of the die pad 16 than the die 12. During subsequent packaging, encapsulation material 22 is placed over the die 12 and portions of the leadframe 18 to form a package 24 as shown in FIG. 1B. The encapsulation material 22 typically has poor adhesion with the epoxy glue 20. In that regard, delamination may occur between the encapsulation material 22 and the epoxy glue 20, as shown by the jagged line 26 in FIG. 1B.

FIG. 2 illustrates another package 30 that involves a prior solution for preventing delamination between the encapsulation material 22 and the epoxy glue 20. In particular, the package 30 includes a leadframe, including the die pad 16 and the leads 18, that has been treated with an anti-wetting agent known to prevent EBO. Generally described, the process involves immersing an entire leadframe strip in a tank filled with the anti-wetting agent. After immersion, the treated leadframe strip is used for packaging a plurality of semiconductor devices and is then typically diced to form individual packages.

Unfortunately, however, the leadframes that have been treated with the anti-wetting agent can have other delamination issues. In particular, delamination may occur between the upper surface 14 of the die pad 16 of the leadframe 32 and the epoxy glue 20 securing the die 12 to the die pad 16 as shown by the jagged line 34 in FIG. 2.

### BRIEF SUMMARY

Embodiments of the present disclosure are directed to packages that include a leadframe having a surface that is selectively treated with an anti-wetting agent and methods of forming a packing comprising same. In one embodiment there is provided a die pad of a leadframe having an upper surface that includes a first portion that has been treated with an anti-wetting agent and a second portion located within the first portion. The second portion has not been treated with the anti-wetting agent. A semiconductor die is attached to the upper surface of the leadframe at the second portion.

### BRIEF DESCRIPTION OF THE SEVERAL VIEWS OF THE DRAWINGS

FIG. 1A is a plan view of a package without encapsulation material in accordance with the prior art.

FIG. 1B is a cross-sectional view of the package of FIG. 1A along line A-A and with encapsulation material in accordance with the prior art.

FIG. 2 is a cross-sectional view of another package in accordance with the prior art.

FIG. 3A is a plan view of a package without encapsulation material in accordance with one embodiment of the disclosure.

FIG. 3B is a cross-sectional view of the package in FIG. 3A along line B-B with encapsulation material.

FIG. 4 is a plan view of another package without encapsulation material in accordance with another embodiment of the disclosure.

FIGS. 5A and 5B illustrate a method for selectively treating a leadframe in accordance with one embodiment of the disclosure.

FIG. 6 illustrates another method for selectively treating a leadframe in accordance with another embodiment of the disclosure.

### DETAILED DESCRIPTION

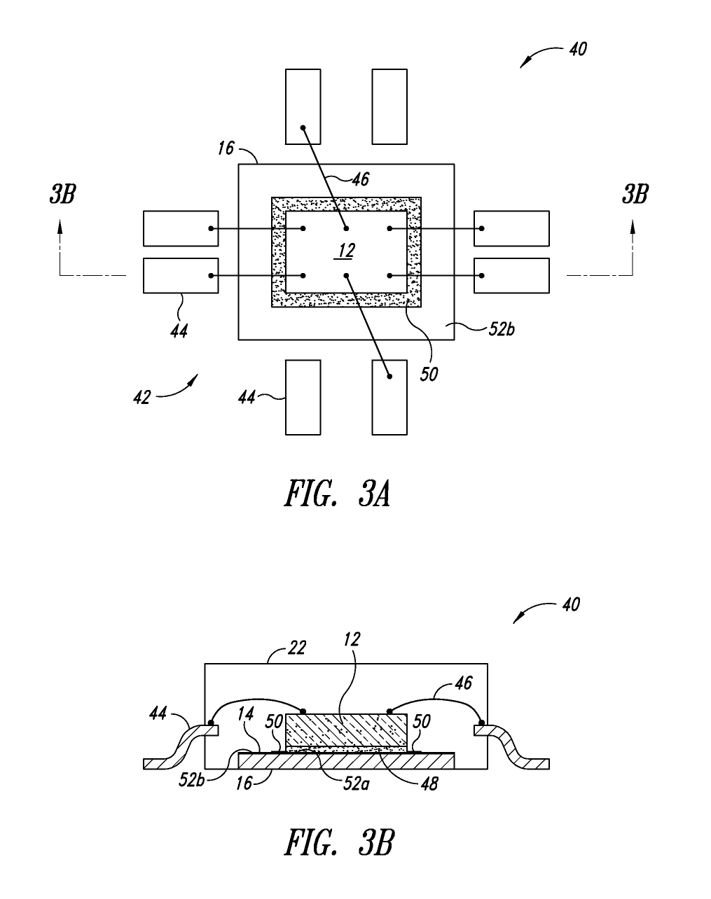

FIG. 3A shows a plan view of a partial package 40 in accordance with one embodiment of the disclosure. The package 40 is partial because it does not include encapsulation material. In contrast, FIG. 3B shows a cross-sectional view of the package 40, with encapsulation material 22.

The package 40 includes a semiconductor die 12 that includes an electrical device, such as a sensor, an electromechanical sensor (MEMS), an integrated circuit, or any other electrical device, located on an upper surface 14 of a die pad 16 of a leadframe 42. The leadframe 42 also includes one or more leads 44 located proximate at least one side of the die pad 16. In the illustrated embodiment, leads 44 surround all four sides of the die pad 16. It is to be appreciated, however, that one or more leads 44 may be located on any number of sides of the die pad 16, including only on one side of the die pad 16.

The leadframe 42 is a conductive material, and may be a metal material, such as copper. In some embodiments, one or more surfaces of the leadframe 42, such as the die pad 16 and the leads 44, are plated with a nanolayer or microlayer of metal materials, such as Ag, Ni/Pd, Ni/Pd/Ag, Ni/Pd/Au—Ag alloy, or Ni/Pd/Au/Ag, to protect the leadframe 42, such as from corrosion and oxidation.

Generally described, the leadframe 42 has a roughened upper surface to increase the adhesive properties of the material. For example, in the embodiment in which the leadframe 42 is plated with Ag, the Ag layer may be treated. In the embodiments in which the leadframe 42 is plated with one of NiPd, NiPd Au—Ag alloy and NiPdAuAg, the Ni layer may be roughened.

Conductive wires 46 electrically couple the die 12 to respective leads 44, which provides electrical connection outside of the package 40. As discussed above and shown in FIG. 3B, encapsulation material 22 surrounds the die 12, portions of the die pad 16, and portions of the leads 44 to provide protection from environmental sources of damage, such as corrosion, physical damage, moisture damage, or other causes of damage to electrical devices.

The die 12 is secured to the upper surface 14 of the die pad 16 by a flowable adhesive material 48, such as glue, paste, solder, or any other flowable adhesive. In one embodiment, the adhesive material 48 is an epoxy glue and may include resin and a filler material.

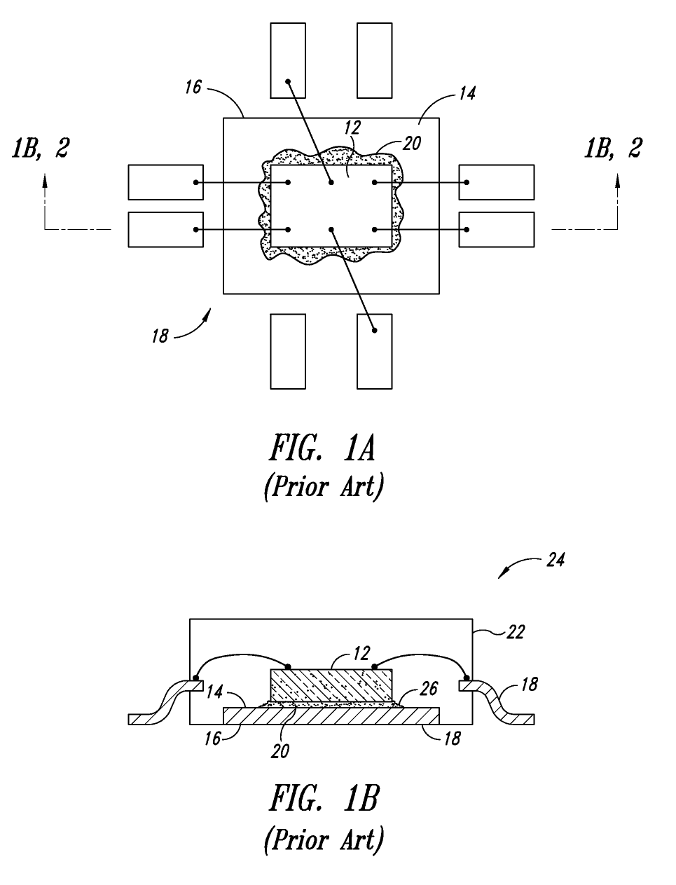

The upper surface 14 of the die pad 16 is selectively treated with the anti-wetting agent to reduce adhesive bleed out described above, while at the same time maintaining properties for suitable adhesive strength with the adhesive material 48 and the encapsulation material 22. In particular, a first portion 50 of upper surface 14 of the die pad 16 has been treated with an anti-wetting agent, while second and third portions 52a, 52b of the leadframe remain untreated. In the illustrated embodiment, the first portion 50 that has been treated with the anti-wetting agent has a first side located outwardly of both the die 12 and the adhesive material 48 and a second side that is spaced apart from an outer edge of the die pad 16. The treated first portion 50 prevents the adhesive material 48 from flowing over the upper surface 14 of the die pad 16 as described above in relation to FIG. 1A. In that regard, the adhesive material 48 has a foot print that substantially the same size as the die 12.

Various types of anti-wetting agents for reducing adhesive bleed out are commercially available. One examples is referred to as Anti EBO T13, which is a neutral pH, sold by Atotech.

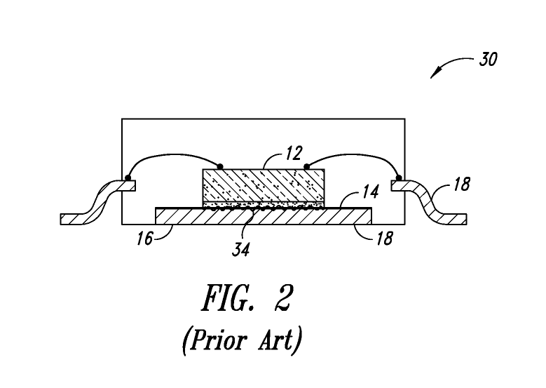

As indicated above, the remaining portions that have not been treated with the anti-wetting agent include the second portion 52a located under the die 12 and a third portion 52b located at the outer perimeter of the die pad 16. In one embodiment, the second portion 52a is substantially the same size and shape of the die 12 or slightly larger than the die 12. In one embodiment, the second portion 52a has an area that is less than 5% larger than the area of the die 12. The untreated second portion 52a of upper surface 14 of the die pad 16 provides suitable adhesion properties with the adhesive material 48. In that regard, the untreated second portion 52a eliminates or reduces delamination issues between the die 12 and the die pad 16 discussed above in reference to FIG. 2. That is, selective treatment of upper surface 14 of the die pad 16 of the leadframe 42 eliminates or at least reduces the various delamination issues discussed above.

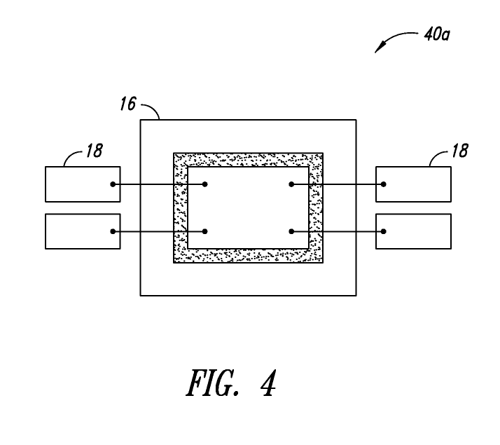

FIG. 4 shows another plan view of a package 40a without encapsulation material in accordance with another embodiment of the disclosure. The package 40a of FIG. 4 is substantially identical to the package 40 of FIG. 3 except that the package 40a of FIG. 4 includes leads 18 proximate two sides of the die pad 16, rather than the four sides of the package 40 of FIG. 3. As indicated above, one or more leads 18 may be located proximate to any number of sides of the die pad 16 including one side.

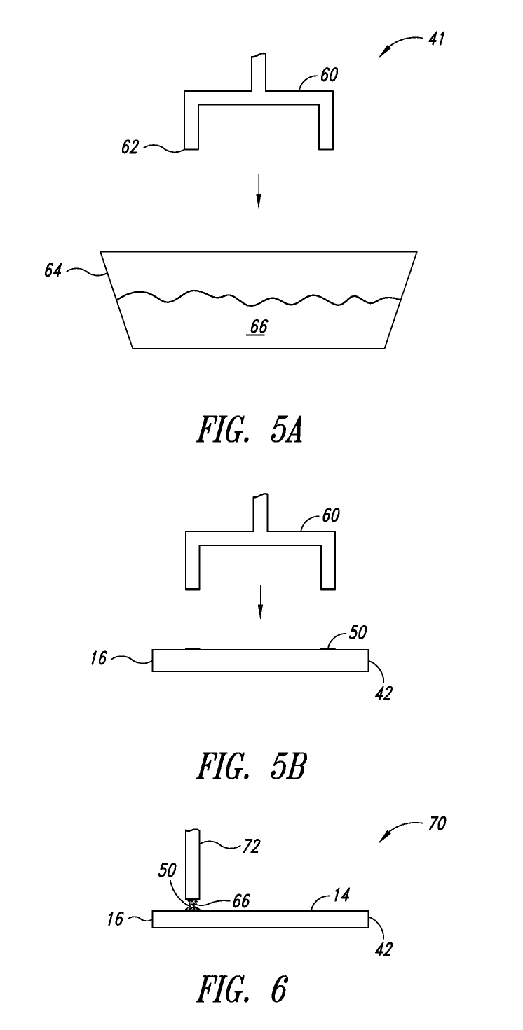

FIGS. 5A and 5B illustrate a method 41 for selectively treating the upper surface 14 of the die pad 16 of the leadframe 42 in accordance with one embodiment of the present disclosure. In particular, FIGS. 5A and 5B illustrate depositing the anti-wetting agent on the first portion of the upper surface of the die pad using a stamping method. The stamping method involves a stamping device 60, shown here in cross section, having a stamping end 62 that has a shape that corresponds to the first portion 50 of the die pad 16 of the leadframe 42 to be treated with the anti-wetting agent. The stamping end 62 is dipped in a tank 64 filled with the anti-wetting agent 66 and is then placed on the upper surface 14 of the die pad 16, thereby treating the first portion 50 of the die pad 16. Although FIG. 5B only shows a die pad 16 of a leadframe, it is to be appreciated, however, that the die pad 16 is part of a leadframe strip that includes a plurality of die pads and a plurality of leads that are connected by tie bars.

In another embodiment, the anti-wetting agent 66 may also be applied by conventional printing techniques. For instance, the anti-wetting agent 66 may be applied by screen-printing, in which the anti-wetting may be applied to the die pad by pressing the anti-wetting agent through holes in a screen.

FIG. 6 illustrates another method 70 for selectively treating the upper surface 14 of the die pad 16 of the leadframe 42 in accordance with another embodiment of the present disclosure. In particular, FIG. 6 illustrates a method 70 of dispensing the anti-wetting agent 66 on the die pad 16 of the leadframe 42, such as by using a liquid dispensing device 72. In particular, the liquid dispensing device 72 may be configured to move relative to the upper surface 14 of the die pad 16 of the leadframe 42 (or vice-versa) and dispense the anti-wetting agent 66 at the first portion 50, while not dispensing the anti-wetting agent 66 on the remaining second and third portions 52a, 52b of the die pad 16.

Typically, the upper surface 14 of the die pad 16 of a leadframe strip will be treated with the anti-wetting agent 66 prior to die attach. After the first portion 50 of the die pad 16 has been treated, the packages may be assembled using conventional methods. For instance, the adhesive material 48 may then be deposited on the second portion 52a of the die pad 16. As the die 12 is placed over the adhesive material 48, the adhesive material 48 may flow toward the treated first portion 50 of the die pad 16. As the adhesive material 48 flows into the treated first portion 50, the flow of the adhesive material will substantially slow and/or stop. In that regard, the adhesive material 48 will have reduced bleed out area that surrounds the die pad 16 in comparison with the prior art as discussed in reference to FIG. 1 B.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A leadframe package comprising:
a die pad having an upper surface that is treated at a first location with an anti-wetting agent, the anti-wetting agent configured to reduce adhesive bleed out on the treated upper surface of the die pad at the first location;
at least one lead located proximate to the die pad;
a die secured to the upper surface of the die pad at a second location via an adhesive, the second location being untreated with the anti-wetting agent; and
encapsulation material located over the die and the upper surface of the die pad.

2. The leadframe package of claim 1 wherein first location is located outwardly of the second location.

3. The leadframe package of claim 1 wherein the first location has a rectangular or square shape and the second location being located in the center of the rectangular or square shape of the first location.

4. The leadframe package of claim 3 wherein the first location is outwardly bound a distance from a perimeter of the die pad.

5. The leadframe package of claim 3 wherein the first location has an edge that is equal to or slightly larger than the perimeter of the die pad.

6. The leadframe package of claim 1 the adhesive abuts an edge of the first location.

7. A method of forming a leadframe package, the method comprising:
treating a first portion of an upper surface of a die pad with an anti-wetting agent without treating a second portion of the upper surface, the first portion surrounding the second portion;
dispensing adhesive between the upper surface of the die pad and a semiconductor die;
aligning the die with the upper surface of the die pad;
using the adhesive, securing the die to the upper surface of the die pad at the second portion, thereby allowing the adhesive to bleed out from under the die;
terminating the adhesive bleed out in the treated first portion of the upper surface of the die pad;
electrically coupling a bond pad on the die to a lead; and
encapsulating the die, a portion of the die pad, and a portion of the lead to form the leadframe package.

8. The method of claim 7 wherein treating the first portion of the upper surface of the die pad with the anti-wetting agent comprises depositing the anti-wetting agent on the first portion of the upper surface of the die pad.

9. The method of claim 7 wherein treating the first portion of the upper surface of the die pad with an anti-wetting agent comprises stamping the anti-wetting agent on the first portion of the upper surface of the die pad.

10. The method of claim 9 wherein the first portion of the die pad is located outwardly of the die.

11. The method of claim 9 wherein the first portion of the die pad has an inner perimeter that is slightly larger than the die.

12. A leadframe package comprising:
a die pad having an upper surface with a first portion and a second portion, the first portion being treated with an anti-wetting agent that is configured to reduce adhesive bleed out on the treated first portion and the second portion being untreated with the anti-wetting agent;
leads located proximate to the die pad;
a semiconductor die secured to the die pad via an adhesive; and
encapsulation material located over the die, the upper surface of the die pad, and a portion of the leads.

13. The leadframe package of claim 12 wherein the second portion is located under the die.

14. The leadframe package of claim 12 wherein an outer perimeter of the first portion is located outwardly of the die.

15. The leadframe package of claim 12 wherein the first portion surrounds the second portion.

16. The leadframe package of claim 12 wherein the first portion has an inner perimeter that is equal to or slightly larger than a perimeter of the die.

17. The leadframe package of claim 12 wherein the die pad further includes a third portion located outwardly of the first portion, the third portion being untreated with the anti-wetting agent.
